(19) United States
(12) Patent Application Publication
(10) Pub. No.: US 2006/0104152 A1
(43) Pub. Date: May 18, 2006

(54) Controlling an addressable array of circuits

(76) Inventors: Eric T. Martin, Corvallis, OR (US); Adam L. Ghozeil, Corvallis, OR (US)

Correspondence Address: HEWLETT PACKARD COMPANY, P O BOX 272400, 3404 E. HARMONY ROAD, INTELLECTUAL PROPERTY ADMINISTRATION, FORT COLLINS, CO, 80527-2400, US

(21) Appl. No.: 10/960,998

(22) Filed: Oct. 7, 2004

(51) Int. Cl. G11C 11/06

(52) U.S. Cl. 365/244

(57) ABSTRACT

An addressable array of circuits is grouped into a plurality of sub-arrays. The addressable array of circuits is controlled by selecting a sub-array to reset and independently of the sub-array selected to be reset, selecting a sub-array to load with data. The sub-array selected to be reset is reset. Data is initialized for the sub-array selected to be loaded. The sub-array selected to be loaded is loaded with the initialized data.

### BACKGROUND

Control of an array of circuits, such as diffraction- or interference-based MEMS optical modulators, can be achieved by generating column analog voltage lines (N per column) and digital row control signals (M per row). Precise control of the modulators provides improved control of images displayed using the modulators. This precise control of the modulators can require precise timing control between each of the M row control signals for a given row and precise timing of the pulsewidth of each row signal. Many factors can affect this timing, for example, process variation and usage mode. As a result, the timing may vary from manufactured lot to manufactured lot and even from part to part. Since the timing may vary, it is desirable to easily and precisely accommodate the timing differences for each part.

### DESCRIPTION OF THE DRAWINGS

FIG. 1 is a block diagram of an embodiment of a display system of the present invention.

FIG. 2 is a block diagram of one embodiment of the addressable array of circuits and the sub-array controller of FIG. 1.

FIG. 3 is an illustration of an embodiment of one of the circuits of the addressable array of circuits of FIG. 2.

FIG. 4 is a block diagram of one embodiment of the sub-array controller of FIG. 2.

FIG. 5 is a block diagram of one embodiment of the sub-array decoder of FIG. 4.

FIG. 6 is a block diagram of an alternate embodiment of the sub-array controller of FIG. 2.

FIG. 7 is a flow chart illustrating one embodiment of the present invention method for controlling an addressable array of circuits grouped into a plurality of sub-arrays.

### DETAILED DESCRIPTION OF THE INVENTION

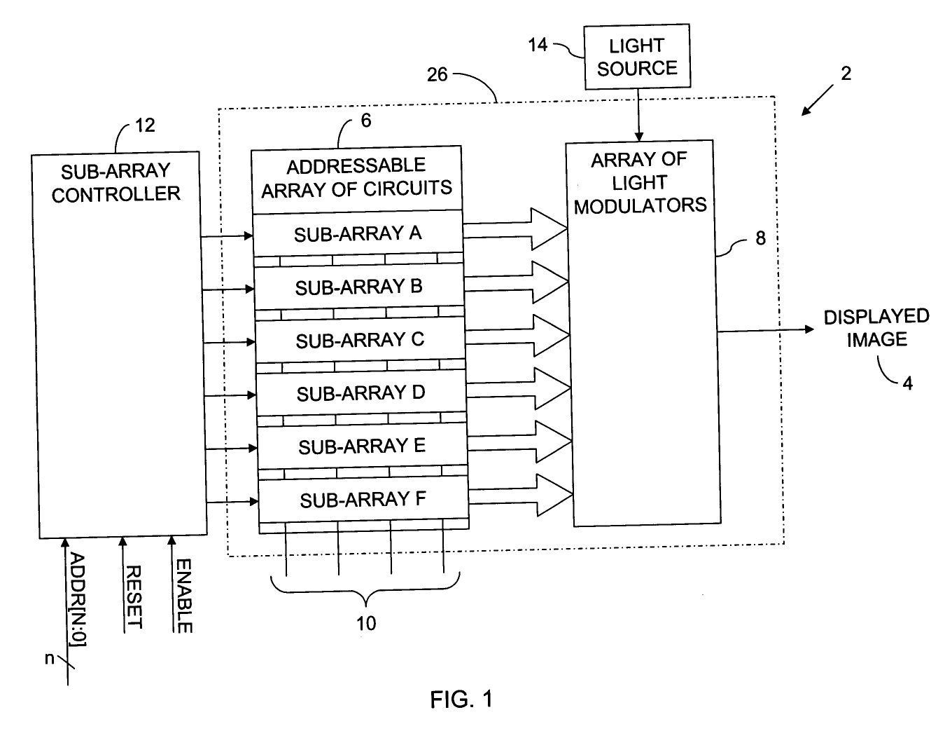

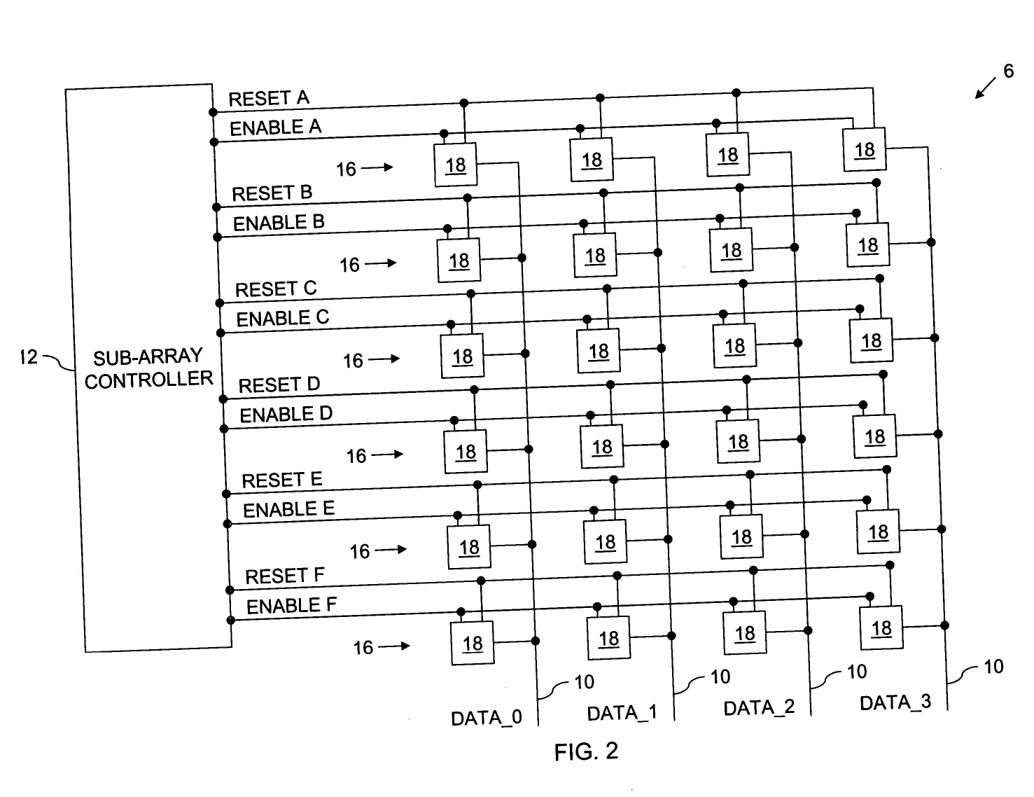

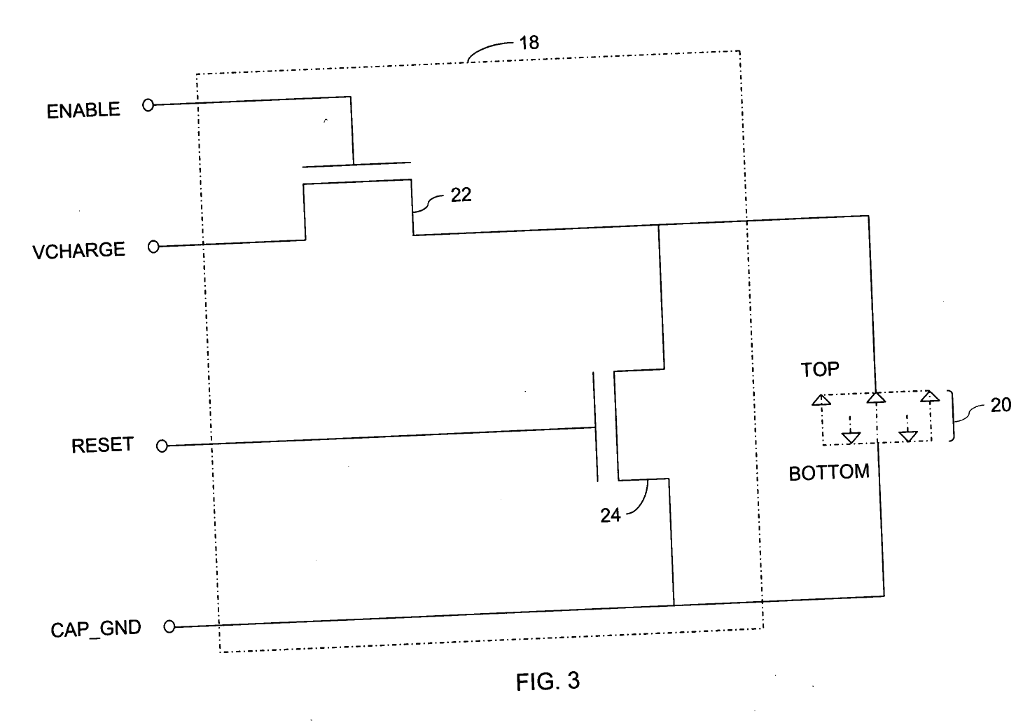

FIG. 1 shows one embodiment of a display system 2 for displaying an image 4. Display system 2 includes an addressable array 6 of circuits 18 (FIGS. 2-3), an array 8 of light modulators, data signal conveyors 10, a sub-array controller 12, and a light source 14. In one embodiment, addressable array 6 of circuits 18, data signal conveyors 10, and sub-array controller 12 comprise an integrated circuit. Additional components may be present between and around the illustrated components in order to provide additional functionality. For example, a system controller may provide the inputs to sub-array controller 12 and display optics may be used to focus the output of array 8 of light modulators.

FIG. 2 shows a block diagram of one embodiment of addressable array 6 of circuits 18. Addressable array 6 of circuits 18 is grouped into a plurality of sub-arrays 16. Examples of sub-arrays 16 include rows and columns. Each sub-array 16 includes at least one circuit 18.

FIG. 3 illustrates one example of circuit 18. Controlled by circuit 18 is a microelectromechanical variable capacitor 20. MEMS capacitance is controlled by manipulating the charge or voltage on MEMS capacitor 20. MEMS capacitor 20 may be charged and discharged by switch 22 and 24, respectively. Switches 22 and 24 may include one or more PMOS or NMOS transistors.

To charge, or actuate, MEMS capacitor 20, a vcharge signal is provided to switch 22; following which an enable signal is pulsed for an appropriate pulse width. The enable signal turns on switch 22, allowing the vcharge signal to charge MEMS capacitor 20. The appropriate pulse width for the enable signal is the time necessary to charge MEMS capacitor 20. The time necessary to charge MEMS capacitor 20 may be a function of electrical and mechanical time constants of the system, including the capacitance of MEMS capacitor 20 and the resistance of the system. The polarity of the enable signal is determined by the implementation of the circuit 18. When it is desired to reset MEMS capacitor 20, a reset signal is pulsed for enough time to drain a desired amount of charge off of the node “top” of MEMS capacitor 20. In one embodiment, the desired amount of charge is the amount of charge necessary to change the position of one of the light modulators in the array 8 of light modulators.

To form addressable array 6, circuit 18 is replicated in M rows and N columns. The analog voltage signal vcharge is a column signal (i.e., all array elements in a particular column use the same vcharge), and the digital signals “enable” and “reset” are row signals (i.e., all array elements in a particular row use the same “enable” and “reset”). As shown in FIG. 2, signals data_0-data_3 represent vcharge signals.

In control of the array 6, the timing of the pulse width of n-enable, the pulse width of reset, and the delay between enable and reset may be important. In one example, the timing of these parameters is necessary to properly coordinate the timing of the array 8 of light modulators. The timing for these three parameters may require calibration on a per lot, per wafer, or per part basis.

Referring again to FIG. 1, array 8 of light modulators is any system or apparatus having a plurality of reflective, transmissive, or transreflective surfaces, or combinations thereof, controllable by array 6 of circuits. In one embodiment, array 8 of light modulators includes an array of mirrors. In one embodiment, addressable array 6 of circuits 18 and array 8 of light modulators together comprise a MEMS spatial optical modulator array 26.

Light source 14 is any source of light suitable for use in a projector. Furthermore, light source 14 may be a white or color light source, such as a sequential color light source. One example of such a suitable white light source 14 is an ultra high-pressure mercury lamp. One example of a color light source is a white light source in cooperation with a color filter wheel.

Data signal conveyors 10 are any apparatus, or system configured to convey data signals to each of the circuits 18 in addressable array 6 of circuits. Examples of data signal conveyors 10 include electrically conductive lines and optically conductive lines.

Sub-array controller 12 is in communication with addressable array 6 of circuits 18. Sub-array controller 12 is configured to select a sub-array to reset; select, independently of a sub-array selected to be reset, a sub-array to load with data; reset the sub-array selected to be reset; and load the sub-array selected to be loaded with data from the data signal conveyors. In one embodiment, sub-array controller 12 receives Addr[n:0], Enable, and Reset signals. These signals are used by sub-array controller 12 to generate the reset and enable signals output by sub-array controller 12 to array 6. The Addr[n:0], Enable, and Reset signals may be received from any source, such as a system controller (not shown). In one embodiment, the system controller is embodied on an integrated circuit with sub-array controller 12. In an alternate embodiment, the system controller is embodied on a separate integrated circuit from sub-array controller 12.

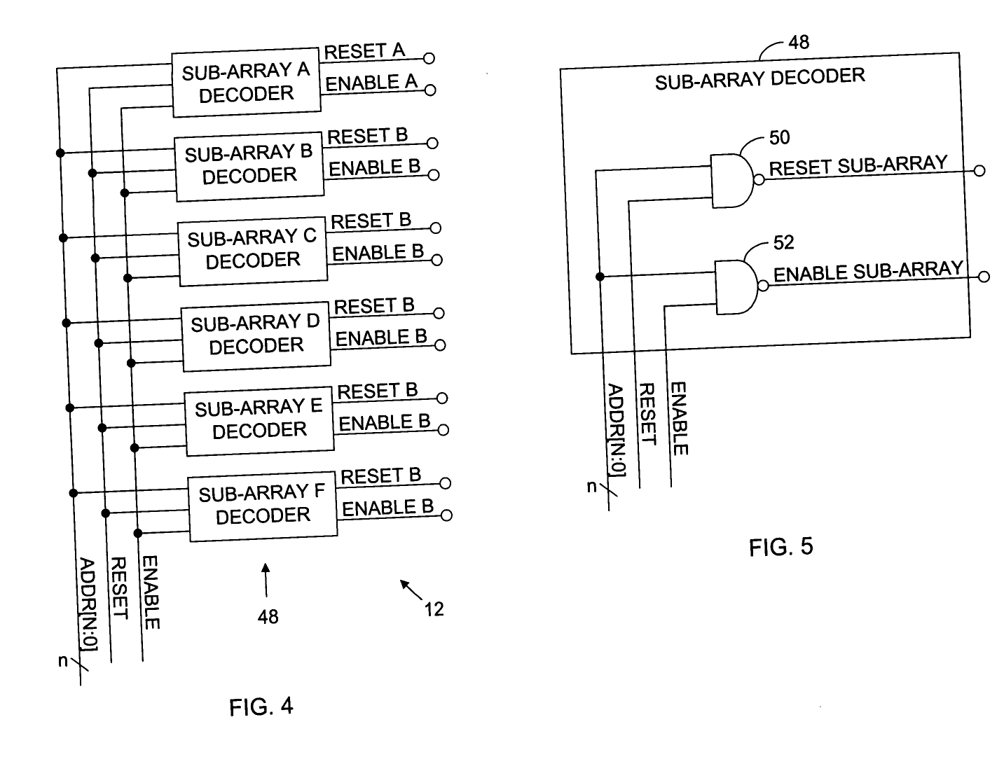

FIG. 4 shows one embodiment of sub-array controller 12. In this embodiment, sub-array controller 12 includes a plurality of sub-array decoders 48. Each sub-array decoder 48 generates sub-array reset and enable signals in response to the Addr[n:0], Enable, and Reset signals. The sub-array decoders 48 may be implemented in many ways.

FIG. 5 illustrates one embodiment of a sub-array decoder 48. Sub-array decoder 48 includes a pair of logical NAND gates 50, 52. Each logical NAND gate 50, 52 receives the Addr[n:0] signal and one of the reset and enable signals. The output of the logical NAND gates 50, 52 are the sub-array enable and sub-array reset signals.

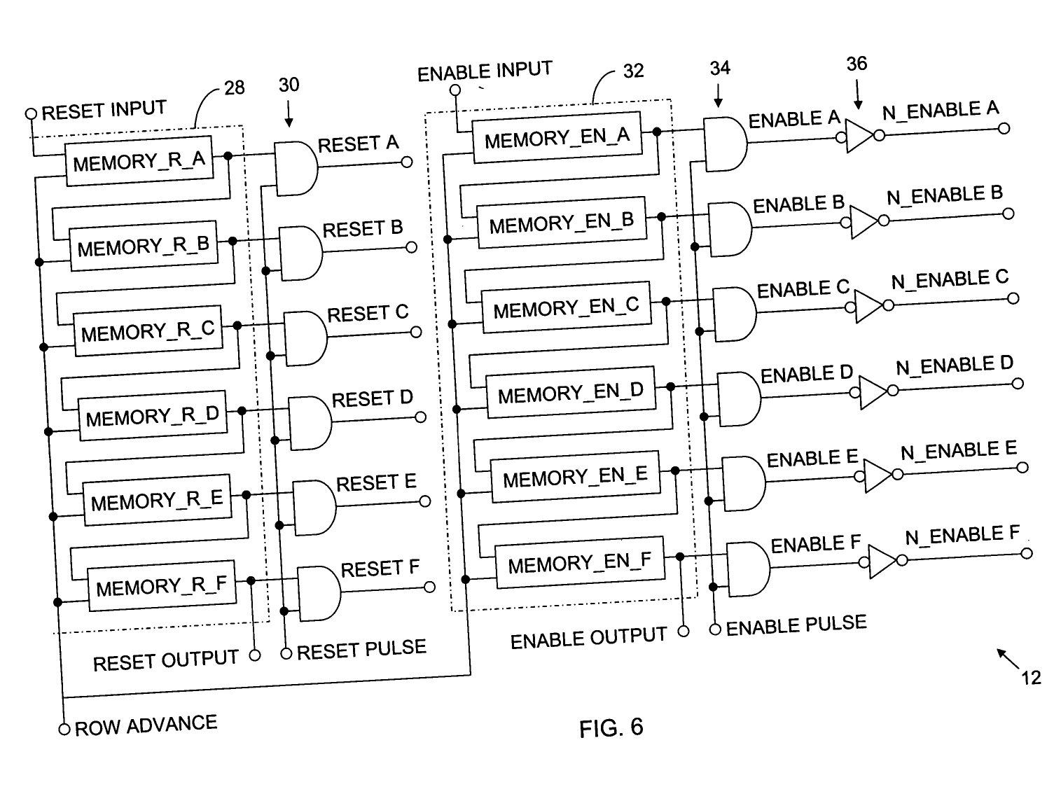

FIG. 6 illustrates an alternate embodiment of sub-array controller 12. In this embodiment, sub-array controller 12 includes a reset shift register 28, a plurality of reset logical AND gates 30, an enable shift register 32, a plurality of enable logical AND gates 34, and a plurality of inverters 36.

Reset shift register 28 is configured to select the sub-array 16 to reset. A plurality of logical AND gates 30 are arranged to receive a reset pulse and the outputs of reset shift register 28 and to output a reset signal to a sub-array 16 selected to be reset. In one embodiment, reset shift register 28 includes a plurality of cells, memory_r_a-memory_r_f. Each cell, memory_r_a-memory_r_f, is in communication with one of the sub-arrays 16.

Enable shift register 32 is configured to select the sub-array 16 to load with data. A plurality of logical AND gates 34 are arranged to receive an enable pulse and the outputs of the enable shift register and to output an enable signal to the sub-array 16 selected to be loaded. In one embodiment, enable shift register 28 includes a plurality of cells, memory_en_a-memory_en_f. Each cell, memory_en_a-memory_en_f, is in communication with one of the sub-arrays 16.

Optionally, inverters 36 are arranged to receive the outputs of logical AND gates 34 and to output an enable signal to a sub-array 16 selected to be loaded. Whether inverters 36 are desired depends on the implementation of the circuits 18, as shown in FIG. 3.

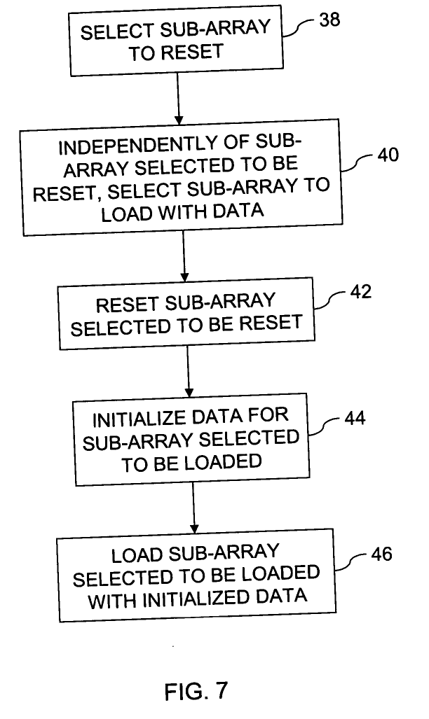

FIG. 7 is a flow chart representing steps of one embodiment of the present invention method for displaying an image on a display surface. Although the steps represented in FIG. 7 are presented in a specific order, the present invention encompasses variations in the order of steps. Furthermore, additional steps may be executed between the steps illustrated in FIG. 7 without departing from the scope of the present invention.

A sub-array 16 to reset is selected 38. In one embodiment, selecting 38 the sub-array 16 to be reset includes applying a reset input signal to the sub-array decoders 48 of sub-array controller 12. The sub-array decoders 48 are selectively addressed by applying an address signal to sub-array controller 12. The addressed sub-array decoder 48 generates a reset sub-array signal in response to the reset input signal.

In another embodiment, selecting 38 the sub-array 16 to be reset includes applying a reset input signal to reset shift register 28. The reset input signal is then propagated through the cells, memory_r_a-memory_r_f, of reset shift register 28 until the reset input signal resides in a cell, memory_r_a-memory_r_f, in communication with the sub-array 16 to be reset.

Independently of the sub-array 16 selected 38 to be reset, a sub-array to load with data is selected 40. In one embodiment, selecting 40 the sub-array 16 to load with data includes applying an enable input signal to the sub-array decoders 48 of sub-array controller 12. The sub-array decoders 48 are selectively addressed by applying an address signal to sub-array controller 12. The addressed sub-array decoder 48 generates an enable sub-array signal in response to the reset input signal.

In one embodiment, selecting 40 the sub-array 16 to load with data includes applying an enable input signal to enable shift register 32. The enable input signal is then propagated through the cells, memory_en_a-memory_en_f, of enable shift register 32 until the enable input signal resides in a cell, memory_en_a-memory_en_f, in communication with the sub-array 16 to be loaded with data.

The sub-array 16 selected to be reset is reset 42. In one embodiment, resetting 42 includes applying a reset signal to each of the circuits 18 in the sub-array 16 selected to be reset.

Data for the sub-array 16 selected to be loaded is initialized 44. In one embodiment, initializing 44 data includes applying data signals to each of the circuits 18 in the sub-array 16 selected to be loaded. For example, data may be applied to data lines data_0-data_4 in FIG. 2.

The sub-array 16 selected to be loaded is loaded 46 with the initialized data. In one embodiment, loading 46 the initialized data includes applying an enable signal to each of the circuits 18 in the sub-array 16 selected to be loaded.

The invention described herein allows for more precise timing control of digital row signals and programmability of that control based on process and other variations. The timing of the rows being reset and the rows being loaded with data is independent of one another. The system is optimizable for process and other variations that may affect MEMS performance. Added control of row signal timing is added with a minimal amount of silicon area consumed on an integrated circuit.

The foregoing description is only illustrative of the invention. Various alternatives, modifications, and variances can be devised by those skilled in the art without departing from the invention. Accordingly, the present invention embraces all such alternatives, modifications, and variances that fall within the scope of the appended claims.

What is claimed is:

1. A method for controlling an addressable array of circuits grouped into a plurality of sub-arrays, the method comprising:
selecting a sub-array to reset;
independently of the sub-array selected to be reset, selecting a sub-array to load with data;
resetting the sub-array selected to be reset;
initializing data for the sub-array selected to be loaded; and
loading the sub-array selected to be loaded with the initialized data.

2. The method of claim 1 wherein selecting the sub-array to be reset includes:
applying a reset input signal to a plurality of sub-array decoders, each sub-array decoder in communication with one of the plurality of sub-arrays;
selectively addressing the sub-array decoder in communication with the sub-array to be reset; and
the addressed sub-array decoder generating a reset sub-array signal in response to the reset input signal.

3. The method of claim 1 wherein selecting the sub-array to be reset includes:
applying a reset input signal to a reset shift register having a plurality of cells, each cell in communication with one of the plurality of sub-arrays and
propagating the reset input signal through the cells of the reset shift register until the reset input signal resides in a cell in communication with the sub-array to be reset.

4. The method of claim 1 wherein selecting the sub-array to load with data includes:
applying an enable input signal to a plurality of sub-array decoders, each sub-array decoder in communication with one of the plurality of sub-arrays;
selectively addressing the sub-array decoder in communication with the sub-array to load with data; and
the addressed sub-array decoder generating an enable sub-array signal in response to the reset input signal.

5. The method of claim 1 wherein selecting the sub-array to load with data includes:
applying an enable input signal to an enable shift register having a plurality of cells, each cell in communication with one of the plurality of sub-arrays and
propagating the enable input signal through the cells of the enable shift register until the enable input signal resides in a cell in communication with the sub-array to load with data.

6. The method of claim 1 wherein resetting includes applying a reset signal to each of the circuits in the sub-array selected to be reset.

7. The method of claim 1 wherein initializing data includes applying data signals to each of the circuits in the sub-array selected to be loaded.

8. The method of claim 1 wherein loading includes applying an enable signal to each of the circuits in the sub-array selected to be loaded.

9. An integrated circuit comprising:
an addressable array of circuits grouped into a plurality of sub-arrays;
data signal conveyors configured to convey data signals to each of the circuits; and
a sub-array controller in communication with the addressable array of circuits, the sub-array controller configured to
select a sub-array to reset;
select, independently of a sub-array selected to be reset, a sub-array to load with data;
reset the sub-array selected to be reset; and
load the sub-array selected to be loaded with data from the data signal conveyors.

10. The integrated circuit of claim 9 wherein the sub-array controller includes a plurality of sub-array decoders configured to select the sub-array to reset and the sub-array to load with data, each sub-array decoder in communication with one of the plurality of sub-arrays.

11. The integrated circuit of claim 9 wherein the sub-array controller includes a reset shift register configured to select the sub-array to reset.

12. The integrated circuit of claim 11 wherein the sub-array controller further includes a plurality of logical AND gates arranged to receive the outputs of the reset shift register and a reset pulse and output a reset signal to a sub-array selected to be reset.

13. The integrated circuit of claim 9 wherein the sub-array controller includes an enable shift register configured to select the sub-array to load with data.

14. The integrated circuit of claim 13 wherein the sub-array controller further includes a plurality of logical AND gates arranged to receive the outputs of the enable shift register and an enable pulse and output an enable signal to a sub-array selected to be loaded.

15. The integrated circuit of claim 14 wherein the sub-array controller further includes a plurality of inverters arranged to receive the outputs of the logical AND gates and output an enable signal to a sub-array selected to be loaded.

16. A display device comprising:
an addressable array of circuits grouped into a plurality of sub-arrays;
an array of light modulators controlled by the array of circuits;
data signal conveyors configured to convey data signals to each of the circuits;
a sub-array controller in communication with the addressable array of circuits, the sub-array controller configured to
select a sub-array to reset;
select, independently of a sub-array selected to be reset, a sub-array to load with data;
reset the sub-array selected to be reset; and
load the sub-array selected to be loaded with data from the data signal conveyors; and
a light source arranged to provide light to the array of light modulators.

17. The display device of claim 16 wherein the sub-array controller includes a plurality of sub-array decoders configured to select the sub-array to reset and the sub-array to load with data, each sub-array decoder in communication with one of the plurality of sub-arrays.

18. The display device of claim 16 wherein the sub-array controller includes a reset shift register configured to select the sub-array to reset.

19. The display device of claim 18 wherein the sub-array controller further includes a plurality of logical AND gates arranged to receive the outputs of the reset shift register and a reset pulse and output a reset signal to a sub-array selected to be reset.

20. The display device of claim 16 wherein the sub-array controller includes an enable shift register configured to select the sub-array to load with data.

21. The display device of claim 20 wherein the sub-array controller further includes a plurality of logical AND gates arranged to receive the outputs of the enable shift register and an enable pulse and output an enable signal to a sub-array selected to be loaded.

22. The display device of claim 21 wherein the sub-array controller further includes a plurality of inverters arranged to receive the outputs of the logical AND gates and output an enable signal to a sub-array selected to be loaded.

23. An integrated circuit comprising:
an addressable array of circuits grouped into a plurality of sub-arrays;
data signal conveyors configured to convey data signals to each of the circuits; and
means for selecting a sub-array to reset;
means for selecting, independently of a sub-array selected to be reset, a sub-array to load with data;
means for resetting the sub-array selected to be reset; and
means for loading the sub-array selected to be loaded with data from the data signal conveyors.

24. The integrated circuit of claim 23 wherein the means for selecting the sub-array to be reset includes a plurality of sub-array decoders configured to select the sub-array to reset, each sub-array decoder in communication with one of the plurality of sub-arrays.

25. The integrated circuit of claim 23 wherein the means for selecting the sub-array to be reset includes a reset shift register having a plurality of outputs in communication with each of the circuits.

26. The integrated circuit of claim 25 wherein the means for selecting the sub-array to be reset further includes a plurality of logical AND gates arranged to receive the outputs of the reset shift register and a reset pulse and output a reset signal to a sub-array selected to be reset.

27. The integrated circuit of claim 23 wherein the means for selecting the sub-array to load with data includes a plurality of sub-array decoders configured to select the sub-array to reset, each sub-array decoder in communication with one of the plurality of sub-arrays.

28. The integrated circuit of claim 23 wherein the means for selecting the sub-array to load with data includes an enable shift register having a plurality of outputs in communication with each of the circuits.

29. The integrated circuit of claim 28 wherein the means for selecting the sub-array to load with data further includes a plurality of logical AND gates arranged to receive the outputs of the enable shift register and an enable pulse and output an enable signal to a sub-array selected to be loaded.

30. The integrated circuit of claim 29 wherein the sub-array controller further includes a plurality of inverters arranged to receive the outputs of the logical AND gates and output an enable signal to a sub-array selected to be loaded.

31. A display device comprising:
an addressable array of circuits grouped into a plurality of sub-arrays;
an array of light modulators controlled by the array of circuits;
data signal conveyors configured to convey data signals to each of the circuits;
means for selecting a sub-array to reset;
means for selecting, independently of a sub-array selected to be reset, a sub-array to load with data;
means for resetting the sub-array selected to be reset; and
means for loading the sub-array selected to be loaded with data from the data signal conveyors; and
means for providing light to the array of light modulators.

32. The display device of claim 31 wherein the means for selecting the sub-array to be reset includes a plurality of sub-array decoders configured to select the sub-array to reset, each sub-array decoder in communication with one of the plurality of sub-arrays.

33. The display device of claim 31 wherein the means for selecting the sub-array to be reset includes a reset shift register having a plurality of outputs in communication with each of the circuits.

34. The display device of claim 33 wherein the means for selecting the sub-array to be reset further includes a plurality of logical AND gates arranged to receive the outputs of the reset shift register and a reset pulse and output a reset signal to a sub-array selected to be reset.

35. The display device of claim 31 wherein the means for selecting the sub-array to load with data includes a plurality of sub-array decoders configured to select the sub-array to reset, each sub-array decoder in communication with one of the plurality of sub-arrays.

36. The display device of claim 31 wherein the means for selecting the sub-array to load with data includes an enable shift register having a plurality of outputs in communication with each of the circuits.

37. The display device of claim 36 wherein the means for selecting the sub-array to load with data further includes a plurality of logical AND gates arranged to receive the outputs of the enable shift register and an enable pulse and output an enable signal to a sub-array selected to be loaded.

38. The display device of claim 37 wherein the sub-array controller further includes a plurality of inverters arranged to receive the outputs of the logical AND gates and output an enable signal to a sub-array selected to be loaded.
